(19) United States
(12) Patent Application Publication
(10) Pub. No.: US 2012/0256161 A1
(43) Pub. Date: Oct. 11, 2012

(54) Light Diode

(76) Inventors: Matthias Sabathil, Regensburg (DE); Simon Kocur, Munchen (DE); Stefan Grötsch, Lengfeld-Bad Abbach (DE)

(21) Appl. No.: 13/260,562

(22) PCT Filed: Mar. 15, 2010
(86) PCT No.: PCT/EP2010/053304

§ 371 Date: Jan. 20, 2012

(30) Foreign Application Priority Data
Mar. 6, 2009 (DE) 10 2009 020 127.0
Mar. 25, 2009 (DE) 10 2009 001 844.1

(51) Int. Cl. H01L 33/04

(52) U.S. Cl. 257/13; 257/E33.008

(57) ABSTRACT

A light-emitting diode is specified, comprising a first semiconductor body (10), which comprises at least one active region (11) which is electrically contact-connected, wherein electromagnetic radiation (110) in a first wavelength range is generated in the active region (11) during the operation of the light-emitting diode, a second semiconductor body (20), which is fixed to the first semiconductor body (10) at a top side (10a) of the first semiconductor body (10), wherein the second semiconductor body (20) has a re-emission region (21) with a multiple quantum well structure (213), and wherein electromagnetic radiation (110) in the first wavelength range is absorbed and electromagnetic radiation in a second wavelength range (220) is re-emitted in the re-emission region (21) during the operation of the light-emitting diode, and a connecting material (30) arranged between the first (10) and second semiconductor body (20), wherein the connecting material (30) mechanically connects the first (10) and the second semiconductor body (20) to one another.

It has been established that the internal efficiency during the generation of electromagnetic radiation for light-emitting diodes which are based on the material system InGaN, for example, decreases, as the wavelength of the generated electromagnetic radiation increases from approximately 80% at a wavelength of 400 nm to approximately 30% at a wavelength of 540 nm. In other words, the internal efficiency for light-emitting diodes which are suitable for generating green light is very low in comparison with light-emitting diodes which emit radiation from the UV range or blue light.

One possibility for increasing the internal efficiency of light-emitting diodes which are suitable for emitting green light could consist, then, in increasing the number of electrically pumped quantum wells. It has been found, however, that narrow limits are imposed on this approach for solving the above-described problem on account of the non-uniform charge carrier distribution during the electrical operation of the light-emitting diode. According to current knowledge, a maximum of two quantum wells can be completely energized in the case of InGaN-based light-emitting diodes which emit green light; the addition of further quantum wells does not appear to have a positive influence on the internal efficiency of the light-emitting diode.

One object to be achieved consists in specifying a light-emitting diode with which electromagnetic radiation can be generated particularly efficiently. A further object to be achieved consists in specifying a light-emitting diode with which green light, in particular can be generated particularly efficiently.

In accordance with at least one embodiment of the light-emitting diode, the light-emitting diode comprises a first semiconductor body. The semiconductor body is grown epitaxially, for example, and can be based on the InGaN-material system. The semiconductor body comprises at least one active region which is electrically contact-connected. Electromagnetic radiation in a first wavelength range is generated in the active region of the first semiconductor body during the operation of the light-emitting diode. In this case, the electromagnetic radiation is generated by means of electrical operation of the active region. The electromagnetic radiation in the first wavelength range is, for example, electromagnetic radiation from the UV range and/or blue light.

In accordance with at least one embodiment of the light-emitting diode, the light-emitting diode comprises a second semiconductor body, which is fixed to the first semiconductor body at a top side of the first semiconductor body. The second semiconductor body, too, is preferably produced epitaxially. The second semiconductor body can be based on the InGaN-material system or the InGaAlP-material system. The second semiconductor body comprises a re-emission region with a multiple quantum well structure. In this case, the designation quantum well structure does not exhibit any significance with regard to the dimensionality of the quantization. It encompasses, inter alia, quantum wells, quantum wires and quantum dots and also any combination of the structures mentioned.

Electromagnetic radiation in the first wavelength range is absorbed and electromagnetic radiation in a second wavelength range is re-emitted in the re-emission region during the operation of the light-emitting diode. In this case, the second wavelength range preferably comprises electromagnetic radiation having greater wavelengths than the first wavelength range. The second wavelength range comprises, in particular, electromagnetic radiation from the wavelength range of green and/or yellow and/or red light.

Particularly with regard to a second semiconductor body based on InGaAlP, the advantage is afforded that, firstly, absorbent current spreading layers and electrical contacts can be dispensed with. Secondly, it is possible to reduce the thermally activated current loss by means of a passivation of the surface facing the first semiconductor body, and thus to reduce the temperature dependence of the efficiency.

The second semiconductor body is therefore preferably arranged in such a way that electromagnetic radiation in the first wavelength range can enter from the first semiconductor body into the second semiconductor body. For this purpose, the second semiconductor body is preferably arranged on a radiation exit area of the first semiconductor body. A large part of the electromagnetic radiation generated in the first semiconductor body enters into the second semiconductor body. In this case, a large part of the electromagnetic radiation is understood to mean at least 50%, preferably at least 70%, particularly preferably at least 85%, of the electromagnetic radiation in the first wavelength range. For this purpose, the second semiconductor body is embodied with a particularly large area and preferably covers the entire radiation exit area at the top side of the first semiconductor body. By way of example, first and second semiconductor bodies terminate flush with one another in a lateral direction or the second semiconductor body projects beyond the first semiconductor body in a lateral direction. In this case, the lateral direction is that direction which is perpendicular to an epitaxial growth direction of the first semiconductor body, for example, or which runs parallel to a layer of the first and of the second semiconductor body, respectively.

In accordance with at least one embodiment of the light-emitting diode, a connecting material is arranged between the first and the second semiconductor body, wherein the connecting material mechanically connects the first and the second semiconductor body to one another.

The connecting material can be, for example, a semiconductor material from which the first and the second semiconductor body are formed. First and second semiconductor bodies are then monolithically integrated with one another.

In this case, first and second semiconductor bodies are produced for example in a single epitaxial growth process and thus embodied in integral fashion. Furthermore, it is possible for first and second semiconductor bodies to be connected to one another by means of a wafer bonding process. The wafer bonding process is direct bonding or anodic bonding, for example. In this case, those surfaces of the two semiconductor bodies which face one another have no roughening and are respectively smoothed, if appropriate, prior to connection.

As an alternative, it is possible for the connecting material to be a transparent, electrically conductive material. By way of example, the connecting material can then be a TCO (Transparent Conductive Oxide) material. In this case, first and second semiconductor bodies can be connected to one another for example by anodic or direct bonding by means of the connecting material.

Furthermore, it is possible, as an alternative, for the connecting material to be electrically insulating. The connecting material can then be, for example, a silicone, a highly refractive silicone having a refractive index of greater than 1.5, an epoxy resin, a silicon oxide or a silicon nitride. First and second semiconductor bodies can then be connected to one another by adhesive bonding or bonding by means of the connecting material.

In accordance with at least one embodiment of the light-emitting diode, the light-emitting diode comprises a first semiconductor body, which comprises at least one active region which is electrically contact-connected, wherein electromagnetic radiation in a first wavelength range is generated in the active region during the operation of the light-emitting diode, and a second semiconductor body, which is fixed to the first semiconductor body at a top side of the first semiconductor body, wherein the second semiconductor body has a re-emission region with a multiple quantum well structure, and wherein electromagnetic radiation in the first wavelength range is absorbed and electromagnetic radiation in a second wavelength range is re-emitted in the re-emission region during the operation of the light-emitting diode. In this case, first and second semiconductor bodies are connected to one another by a connecting material arranged between the first and second semiconductor body.

In the case of the light-emitting diode described, the re-emission region of the second semiconductor body is preferably not electrically contact-connected. In other words, electromagnetic radiation in the re-emission region, that is to say the electromagnetic radiation in the second wavelength range, is not generated by electrical operation of the multiple quantum well structure in the re-emission region, but rather by optical operation. In other words, the light-emitting diode is based on the insight, inter alia, that if the multiple quantum well structure is pumped optically rather than electrically, a uniform charge distribution in the multiple quantum well structure is made possible. As a result of the direct arrangement of the first semiconductor body, which generates shorter-wave electromagnetic radiation during operation, with the second semiconductor body, which generates longer-wave electromagnetic radiation during operation, it is possible to utilize a maximum proportion of the electromagnetic radiation in the first wavelength range for the uniform generation of electron-hole pairs in the multiple quantum well structure of the re-emission region. Furthermore, such a light-emitting diode is distinguished by particularly good spectral and thermal properties. In other words, the active region of the first semiconductor body can be cooled particularly well, for example, since the second semiconductor body acts as a type of heat spreader for the first semiconductor body.

In accordance with at least one embodiment of the light-emitting diode, the first semiconductor body has a multiplicity of coupling-out structures at its top side facing the second semiconductor body. The coupling-out structures can be, for example, a roughening of the first semiconductor body. Furthermore, the coupling-out structures can be pyramid-shaped elevations, or elevations in the shape of truncated pyramids, at the top side of the first semiconductor body. In this case, the coupling-out structures can consist of the material of the semiconductor body and are structured from the material of the first semiconductor body, for example. Furthermore, it is possible for the coupling-out structures to be additional structures which consist of a material which is different from the material of the first semiconductor body. The coupling-out structures preferably consist of a material whose optical refractive index deviates by at most 30% from the refractive index of the first semiconductor body.

In accordance with at least one embodiment of the light-emitting diode, the connecting material encloses the coupling-out structures at their exposed outer areas. In other words, the connecting material is introduced between the first and the second semiconductor body and covers the coupling-out structures. The connecting material can then completely cover the coupling-out structures at the exposed outer areas of the coupling-out structures, such that the coupling-out structures are embedded into the connecting material. It is then possible that the coupling-out structures at the top side of the first semiconductor body do not touch the second semiconductor body, rather connecting material is arranged between the coupling-out structures and the second semiconductor body.

Overall, the coupling-out structures make it possible that electromagnetic radiation in the first wavelength range can emerge from the first semiconductor body and enter into the second semiconductor body with a higher probability than would be the case without the coupling-out structures. The coupling-out structures ensure, for example, that the probability of total reflection of the electromagnetic radiation from the first wavelength range at the interface between the first semiconductor body and second semiconductor body is reduced.

In accordance with at least one embodiment of the light-emitting diode, the second semiconductor body has a multiplicity of coupling-out structures at its top side remote from the first semiconductor body and/or its underside facing the first semiconductor body. The coupling-out structures can be embodied identically or differently with respect to the coupling-out structures of the first semiconductor body. In other words, the coupling-out structures can be structured from the material of the second semiconductor body and thus consist of the material of the second semiconductor body. However, it is also possible for the coupling-out structures to consist of a material which is different from the material of the second semiconductor body.

Preferably, the second semiconductor body has a multiplicity of coupling-out structures at its top side remote from the first semiconductor body and its underside facing the first semiconductor body. The coupling-out structures at the underside of the second semiconductor body advantageously reduce Fresnel losses at the interface between the second semiconductor body and connecting material.

In one embodiment, the coupling-out structures of the second semiconductor body consist of a material whose optical refractive index deviates by at most 30% from the optical refractive index of the second semiconductor body.

The coupling-out structures of the second semiconductor body increase the probability of emergence of light from the second semiconductor body.

In this case, the emerging light can be electromagnetic radiation from the first or the second wavelength range. In other words, the light-emitting diode can emit mixed light from the first and the second wavelength range. The mixed light can be white light, for example.

However, it is also possible for the light-emitting diode to emit predominantly electromagnetic radiation from the second wavelength range. In other words, the predominant portion—for example at least 90%—of the electromagnetic radiation from the first wavelength range which has entered into the second semiconductor body is absorbed in the second semiconductor body. In this way, it is possible for the light-emitting diode to emit colour-pure green, yellow or red light, for example.

In accordance with at least one embodiment of the light-emitting diode, the material of the coupling-out structures of the first and/or of the second semiconductor body contains or consists of one of the following substances: titanium oxide, zinc selenide, aluminium nitride, silicon carbide, boron nitride and/or tantalum oxide. These substances are distinguished by the fact that they have an optical refractive index which deviates by at most 30% from the refractive index of an InGaN-based semiconductor body.

In accordance with at least one embodiment of the light-emitting diode, a mirror layer is fixed to the underside of the first semiconductor body remote from the second semiconductor body. The mirror layer is, for example, a dielectric mirror, a Bragg mirror, a metallic mirror or a combination of the mirrors mentioned. The mirror layer is provided for reflecting electromagnetic radiation in the first wavelength range in the direction of the second semiconductor body. This makes it possible for a particularly large proportion of the electromagnetic radiation in the first wavelength range to enter into the second semiconductor body. Furthermore, the mirror layer can also reflect electromagnetic radiation in the second wavelength range, which electromagnetic radiation is emitted from the second semiconductor body in the direction of the first semiconductor body, in the direction of the second semiconductor body and thus out of the light-emitting diode.

In accordance with at least one embodiment of the light-emitting diode, the multiple quantum structure of the re-emission region comprises at least 20 quantum well layers. The quantum well layers are for example arranged one above another along a growth direction of the second semiconductor body and separated from one another by barrier layers. In this case, it has been found that such a large number of quantum well layers can be occupied uniformly with charge carriers by means of optical pumping and the efficiency of the generation of electromagnetic radiation in the second wavelength range is appreciably increased on account of the high number of quantum well layers. Particularly in the case of the full conversion of blue light or UV radiation to green light, the number of quantum well layers (also quantum films) is important for the efficiency of light generation since photons are only absorbed in the quantum well layers and a sufficient absorption cross section is provided in the case of a high number of quantum well layers. Furthermore, an advantageous shift in the efficiency maximum to higher currents arises in the case of a high number of quantum well layers on account of the lower charge carrier density in the individual wells. Therefore, the full conversion at high current densities of >100 A/cm² can be more efficient than a directly electrically pumped green light-emitting diode.

The light-emitting diode described here is explained in greater detail below on the basis of exemplary embodiments and the associated figures.

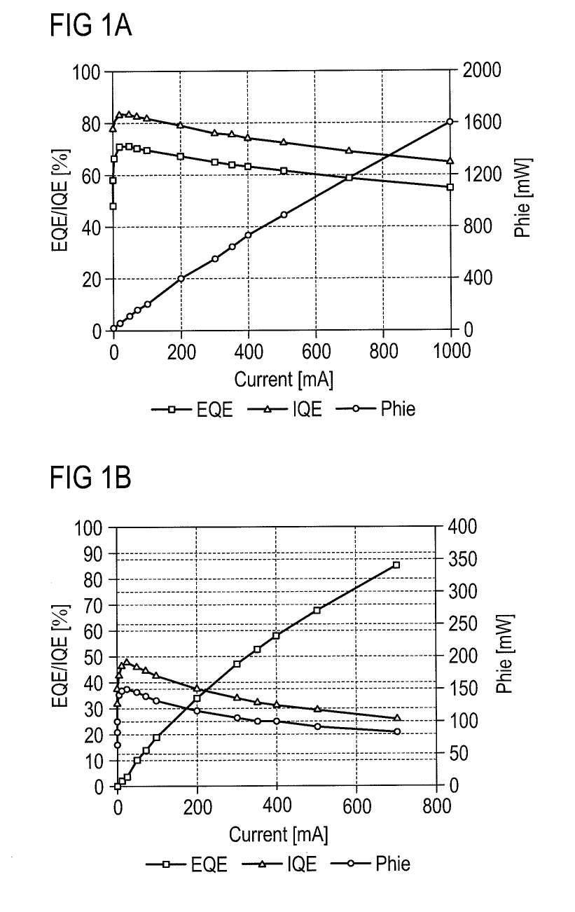

FIGS. 1A and 1B show the efficiency of electrically operated blue and green light-emitting diodes with the aid of graphical plots.

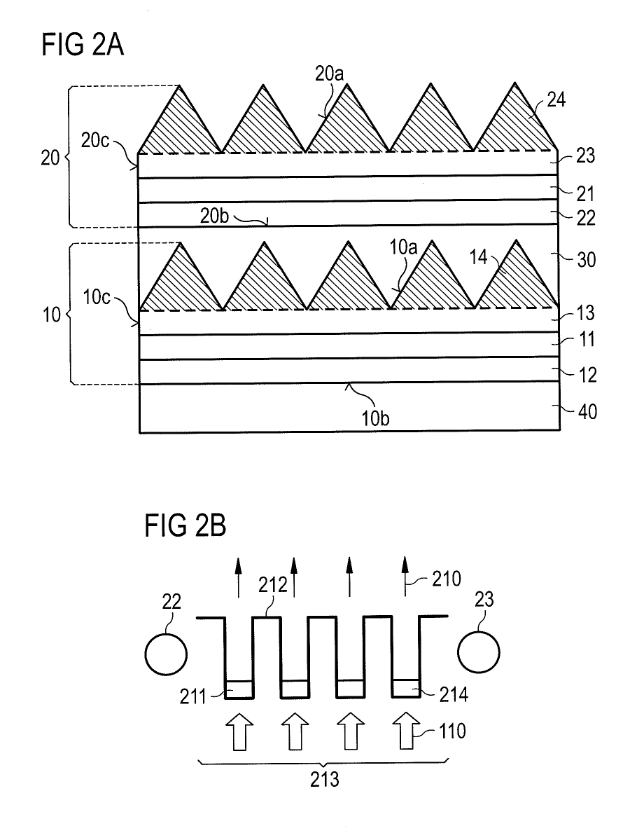

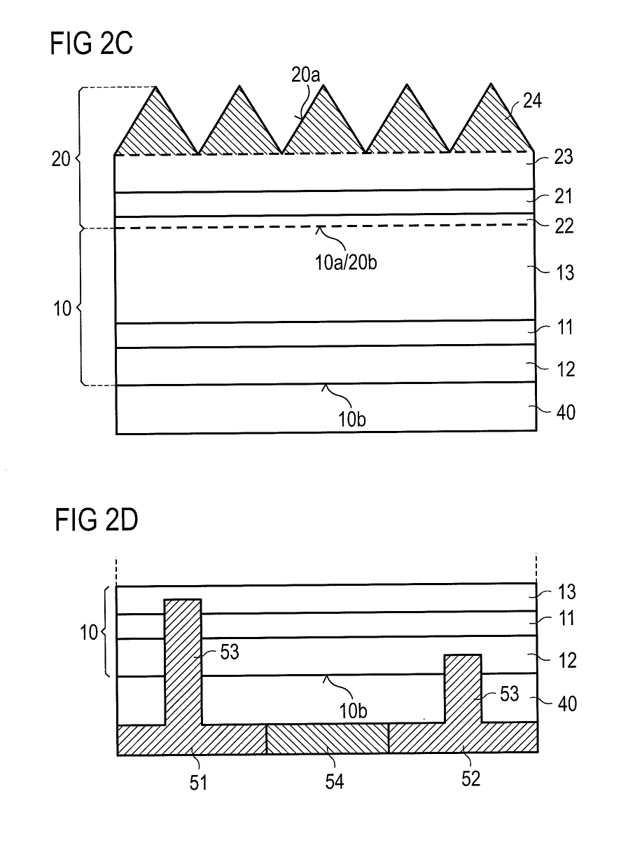

With FIGS. 2A, 2B, 2C and 2D, exemplary embodiments of light-emitting diodes described here are elucidated in greater detail on the basis of schematic sectional illustrations.

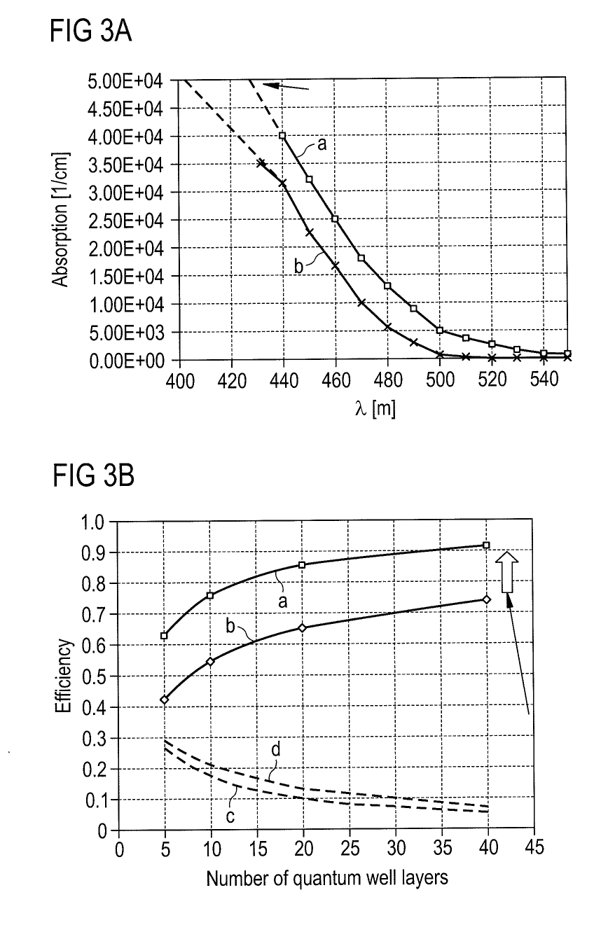

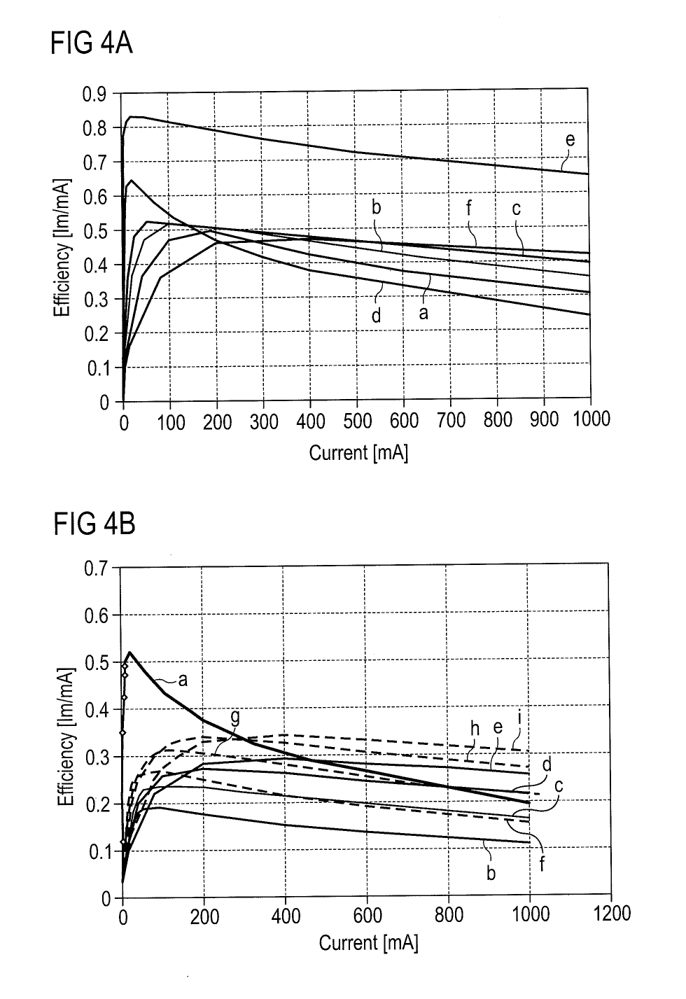

With the aid of the graphical plots in FIGS. 3A, 3B, 4A, 4B, properties of light-emitting diodes described here are elucidated in greater detail.

Elements which are identical, of identical type or act identically are provided with the same reference symbols in the figures. The figures and the size relationships of the elements illustrated in the figures among one another should not be regarded as to scale. Rather, individual elements may be illustrated with an exaggerated size in order that they can be better illustrated and/or for the sake of better understanding.

FIG. 1A shows, on the basis of a graphical plot, the external efficiency (EQE) with optical losses and the internal efficiency without optical losses (IQE) for a light-emitting diode which emits electromagnetic radiation at a peak wavelength of 435 nm, that is to say blue light. The light-emitting diode is electrically operated in this case. As can be seen from FIG. 1A, the internal efficiency is up to above 80%.

FIG. 1B shows, on the basis of a graphical plot, the external efficiency (EQE) and the internal efficiency (IQE) for an electrically operated light-emitting diode which emits green light at a peak wavelength of 540 nm. As can be discerned in FIG. 1B, the maximum internal efficiency is below 50%.

Overall, electrically pumped green light-emitting diodes are inferior to electrically pumped blue light-emitting diodes or light-emitting diodes which emit UV radiation with regard to their efficiency.

FIG. 2A shows a first exemplary embodiment of a light-emitting diode described here on the basis of a schematic sectional illustration. The light-emitting diode in FIG. 2A comprises a first semiconductor body 10 and a second semiconductor body 20. First semiconductor body 10 and second semiconductor body 20 are arranged in a manner stacked one above the other. The second semiconductor body 20 succeeds the first semiconductor body 10 at the top side 10a thereof. The radiation exit area of the first semiconductor body 10 is also situated at the top side 10a, through which radiation exit area emerges the entire or a large part of the electromagnetic radiation 110 emerging from the first semiconductor body 10.

The first semiconductor body 10 comprises a p-doped region 12 and an n-doped region 13. The active region 11 is arranged between the p-doped region 12 and the n-doped region 13. The active region 11 is electrically operated; the electrical connections are not shown in FIG. 2A (in this respect, see FIG. 2D). By way of example, the active region 11 comprises a pn-junction, a single quantum well structure or a multiple quantum well structure. At its top side 10a, the first semiconductor body 10 has coupling-out structures 14, which, in the present case, are formed from the material of the first semiconductor body 10. By way of example, the coupling-out structures are a roughening produced by means of KOH etching. However, the coupling-out structures 14 can also be formed from other materials such as have been described further above.

The second semiconductor body 20 comprises an n-doped region 22, a p-doped region 23 and a re-emission region 21 arranged between the two regions. The re-emission region 21 comprises a multiple quantum well structure. The re-emission region 21 is not electrically connected and is not electrically operated.

At its top side 20a, the second semiconductor body 20 comprises coupling-out structures 24, which, in the present case, are likewise structured by means of KOH etching into the semiconductor body 20. The coupling-out structures 24 can also be formed from other materials such as have been described further above. Coupling-out structures 24 can also be arranged at the underside 20b of the second semiconductor body 20 (not shown in the figure).

A connecting material 30 is arranged between first semiconductor body 10 and second semiconductor body 20, said connecting material in the present case containing silicone or consisting of silicone. The connecting material 30 completely encloses the coupling-out structures 14 of the first semiconductor body 10 at their exposed outer areas. In the present case, the connecting material 30 is electrically insulating and produces a mechanical connection between the two semiconductor bodies.

In the present case, first semiconductor body 10 and second semiconductor body 20 are produced epitaxially separately from one another and subsequently connected to one another by means of the connecting material 30. Second semiconductor body 20 and first semiconductor body 10 terminate flush with one another at their side areas 20c and 10c, with the result that the semiconductor bodies 10, 20 do not project laterally beyond one another.

A mirror layer 40 is arranged at the underside 10b of the first semiconductor body 10 remote from the second semiconductor body 20, said mirror layer in the present case being embodied as a metallic mirror consisting of aluminium or silver, for example. The mirror layer 40 is suitable for the reflection of both electromagnetic radiation 110 from the first wavelength range and electromagnetic radiation 210 from the second wavelength range.

The multiple quantum well structure 213 of the re-emission region 21 is elucidated in greater detail in the schematic sectional illustration in FIG. 2B. The multiple quantum well structure 213 comprises a multiplicity of quantum well layers 211 that are separated from one another by barrier layers 212. Electromagnetic radiation in the first wavelength range 110 leads to a distribution of charge carriers 214 in the quantum well structures which is uniform on account of the optical pumping.

In conjunction with FIG. 2C, a further exemplary embodiment of a light-emitting diode described here is elucidated in greater detail with the aid of a schematic sectional illustration. In this exemplary embodiment, first semiconductor body 10 and second semiconductor body 20 are monolithically integrated. In other words, for example, they are deposited epitaxially one on top of the other in a single epitaxy installation. Furthermore, it is possible for first semiconductor body 10 and second semiconductor body 20 to be connected to one another by means of a wafer bonding process. In the exemplary embodiment, the connecting material 30 is formed by the semiconductor material 13, 22 of first semiconductor body 10 and second semiconductor body 20. The optical coupling between the active region 11 and the re-emission region 21 is advantageously better in this embodiment than in the case of the exemplary embodiment described in conjunction with FIG. 2A, for example. The more complicated production of the exemplary embodiment shown in conjunction with FIG. 2C is disadvantageous.

One possibility for the electrical contact-connection of the active region 11 of the first semiconductor body 10 is elucidated schematically with the aid of the schematic sectional illustration 2D. From the underside 10b of the first semiconductor body 10, in the present case channels 53 are introduced into the semiconductor body 10 through the mirror layer, said channels being filled with an electrically conductive material, which forms electrical contact locations 51, 52 at that side of the mirror layer 40 which is remote from the semiconductor body 10. Besides the embodiment shown, other connection possibilities for the electrical contact-connection of the active layer 11 of the first semiconductor body 10 are also conceivable.

The graphical plot in FIG. 3A shows the absorption in the multiple quantum well structure 213 of the re-emission region 21 for the exemplary embodiment in FIG. 2C (curve a) and the exemplary embodiment in FIG. 2A (curve b) as a function of the wavelength λ of the electromagnetic radiation generated in the active layer 11. It can be discerned here that the absorption is optimal for electromagnetic radiation in the wavelength range of 400 nm, that is to say in the UV range. Therefore, electromagnetic radiation from the UV range is preferably generated in the active layer 11.

FIG. 3B shows, on the basis of a graphical plot, the efficiency plotted against the number of quantum well layers in the multiple quantum well structure 213. In this case, the curves a, b show the efficiency for the exemplary embodiments in FIGS. 2C and 2A, respectively. The curves c and d show the proportion of unconverted pump radiation that still emerges from the system for the exemplary embodiments in FIGS. 2C and 2A respectively. In addition, however, there are still optical losses as a result of absorption, which are higher in the case of the variant in accordance with FIG. 2C than in the case of the variant in accordance with FIG. 2A. It can be discerned that the efficiency rises with the number of quantum well layers 211 in the multiple quantum well structure 213. In this case, it should be taken into consideration that the monolithic structure as described in greater detail in conjunction with FIG. 2C has a higher efficiency than the structure in FIG. 2A, in which silicone having a refractive index of approximately 1.4 is used as connecting material 30 for connecting first semiconductor body 10 and second semiconductor body 20.

FIG. 4A shows, on the basis of a graphical plot, the efficiency plotted against the current intensity with which the active region is operated. The internal efficiency without optical losses is involved here. Since the optical losses are not taken into account, the graphical plot in FIG. 4A relates both to the exemplary embodiment in FIG. 2A and to the exemplary embodiment in FIG. 2C. Curve a shows the efficiency for five optically pumped quantum well layers, curve b for ten, curve c for 20 and curve f for 40 quantum well layers 211 in the multiple quantum well structure 213. Curve e shows the efficiency of the electrically pumped active region 11 which generates UV radiation. As can be seen from FIG. 4A, the internal efficiency increases for higher current intensities. For current intensities above 200 mA, all curves for optically pumped multiple quantum well structures lie above the efficiency for an electrically pumped quantum well structure as plotted in curve d.

FIG. 4B shows a graphical plot of the efficiency plotted against the applied current, with optical losses being taken into account. In this case, the dashed lines relate to monolithically integrated embodiments as shown in conjunction with FIG. 2C. The solid lines relate to embodiments in which first semiconductor body 10 and second semiconductor body 20 are produced separately from one another, as described in conjunction with FIG. 2A. It can be discerned as a general trend that, on account of the lower optical losses, the efficiency is improved for monolithically integrated light-emitting diodes. However, the latter are more complicated in terms of their production method.

Curve a shows the efficiency of an electrically pumped active region with a single quantum well layer, which region generates green light, for comparison. Curve b shows the situation for five quantum well layers, curve c for ten quantum well layers, curve d for 20 quantum well layers and curve e for 40 quantum well layers, in each case with silicone as connecting material 30 between first semiconductor body 10 and second semiconductor body 20.

Curve f shows the situation for five quantum well layers, curve g for 10 quantum well layers, curve h for 20 quantum well layers and curve i for 40 quantum well layers for the case where first semiconductor body 10 and second semiconductor body are monolithically integrated with one another. Overall, the light-emitting diode has a higher efficiency than the electrically pumped quantum well layer starting from a number of approximately 20 optically pumped quantum well layers 211 in the re-emission region 21.

The invention is not restricted to the exemplary embodiments by the description on the basis thereof. Rather, the invention encompasses any novel feature and also any combination of features, which in particular includes any combination of features in the patent claims, even if this feature or this combination itself is not explicitly specified in the patent claims or exemplary embodiments. This patent application claims the priorities of German Patent Applications 102009001844.1 and 102009020127.0, the disclosure content of which is hereby respectively incorporated by reference.

1. A light-emitting diode comprising:
a first semiconductor body, which comprises at least one active region which is electrically contact-connected, wherein electromagnetic radiation in a first wavelength range is generated in the active region during the operation of the light-emitting diode;
a second semiconductor body, which is fixed to the first semiconductor body a top side of the first semiconductor body, wherein the second semiconductor body has a re-emission region with a multiple quantum well structure, and wherein electromagnetic radiation in the first wavelength range is absorbed and electromagnetic radiation in a second wavelength range is re-emitted in the re-emission region during the operation of the light-emitting diode; and
a connecting material arranged between the first and second semiconductor body, wherein the connecting material mechanically connects the first and the second semiconductor body to one another.

2. The light-emitting diode according to claim 1, wherein the connecting material is electrically insulating.

3. The light-emitting diode according to claim 2, wherein the connecting material is silicone or contains a silicone.

4. The light-emitting diode according to claim 1, wherein the first semiconductor body has a multiplicity of coupling-out structures at its top side facing the second semiconductor body.

5. The light-emitting diode according to claim 4, wherein the connecting material encloses the coupling-out structures at their exposed outer areas.

6. The light-emitting diode according to claim 4, wherein the coupling-out structures consist of a material whose refractive index deviates by at most 30% from the refractive index of the first semiconductor body.

7. The light-emitting diode according to claim 1, wherein the second semiconductor body has a multiplicity of coupling-out structures at its top side remote from the first semiconductor body and/or its underside facing the first semiconductor body.

8. The light-emitting diode according to claim 7, wherein the coupling-out structures consist of a material whose refractive index deviates by at most 30% from the refractive index of the second semiconductor body.

9. The light-emitting diode according to claim 4, wherein the coupling-out structures are formed with a material which is different from the material of the first semiconductor body and from the material of the second semiconductor body.

10. The light-emitting diode according to claim 9, wherein the material of the coupling-out structures contains or consists of one of the following substances: TiO₂, ZnS, AlN, SiC, BN, Ta₂O₅.

11. The light-emitting diode according to claim 1, wherein a mirror layer is fixed to the first semiconductor body at the underside of the first semiconductor body remote from the second semiconductor body.

12. The light-emitting diode according to claim 1, wherein the first wavelength range comprises electromagnetic radiation from the wavelength range of UV radiation and/or blue light.

13. The light-emitting diode according to claim 12, wherein the second wavelength range comprises electromagnetic radiation from the wavelength range of green light.

14. The light-emitting diode according claim 1, wherein the multiple quantum well structure of the re-emission region has at least 20 quantum well layers.

15. A light-emitting diode comprising:
a first semiconductor body, which comprises at least one active region which is electrically contact-connected, wherein electromagnetic radiation in a first wavelength range is generated in the active region during the operation of the light-emitting diode;
a second semiconductor body, which is fixed to the first semiconductor body at a top side of the first semiconductor body, wherein the second semiconductor body has a re-emission region with a multiple quantum well structure, and wherein electromagnetic radiation in the first wavelength range is absorbed and electromagnetic radiation in a second wavelength range is re-emitted in the re-emission region during the operation of the light-emitting diode; and
a connecting material arranged between the first and second semiconductor body, wherein the connecting material mechanically connects the first and the second semiconductor body to one another,
wherein the first semiconductor body has a multiplicity of coupling-out structures at its top side facing the second semiconductor body,
wherein the connecting material encloses the coupling-out structures at their exposed outer areas, and
wherein the coupling-out structures are formed with a material which is different from the material of the first semiconductor body and from the material of the second semiconductor body.

16. The light-emitting diode according claim 15, wherein the multiple quantum well structure of the re-emission region has at least 20 quantum well layers.

17. The light-emitting diode comprising:
a first semiconductor body, which comprises at least one active region which is electrically contact-connected, wherein electromagnetic radiation in a first wavelength range is generated in the active region during the operation of the light-emitting diode; and
a second semiconductor body, which is fixed to the first semiconductor body at a top side of the first semiconductor body, wherein the second semiconductor body has a re-emission region with a multiple quantum well structure, and wherein electromagnetic radiation in the first wavelength range is absorbed and electromagnetic radiation in a second wavelength range is re-emitted in the re-emission region during the operation of the light-emitting diode; and
wherein a connecting material arranged between the first and second semiconductor body, wherein the connecting material mechanically connects the first and the second semiconductor body to one another,
wherein the first wavelength range comprises electromagnetic radiation from the wavelength range of UV radiation and/or blue light,
wherein the second wavelength range comprises electromagnetic radiation from the wavelength range of green light, and
the multiple quantum well structure of the re-emission region has at least 20 quantum well layers.
